(19) United States
(12) Patent Application Publication
(10) Pub. No.: US 2021/0035876 A1
(43) Pub. Date: Feb. 4, 2021

(54) SEMICONDUCTOR PACKAGE INCLUDING A CAVITY IN ITS PACKAGE BODY

(71) Applicant: Infineon Technologies AG, Neubiberg (DE)

(72) Inventors: Ralf Otremba, Kaufbeuren (DE); Markus Dinkel, Unterhaching (DE); Josef Hoeglauer, Heimstetten (DE); Angela Kessler, Sinzing (DE)

(73) Assignee: Infineon Technologies AG, Neubiberg (DE)

(21) Appl. No.: 16/939,303

(22) Filed: Jul. 27, 2020

(30) Foreign Application Priority Data
Aug. 2, 2019 (DE) 10 2019 120 886.6

(51) Int. Cl. H01L 23/31; H01L 23/495; H01L 25/065

(52) U.S. Cl. CPC H01L 23/315; H01L 25/0657; H01L 23/49541

(57) ABSTRACT

A semiconductor package is disclosed. In one example, the semiconductor package includes a package body and a semiconductor component encapsulated in the package body. A cavity is formed in a bottom surface of the package body.

### CROSS-REFERENCE TO RELATED APPLICATION

This Utility patent application claims priority to German Patent Application No. 10 2019 120 886.6, filed Aug. 2, 2019, which is incorporated herein by reference.

### TECHNICAL FIELD

The present disclosure relates to semiconductor technology in general. More particular, the present disclosure relates to a semiconductor package including a cavity in its package body. In addition, the present disclosure relates to an electronic system including such a semiconductor package.

### BACKGROUND

Electronic systems may include circuit boards with various electronic components, such as e.g. semiconductor packages, mounted thereon. Over time circuit board systems have decreased in size and will continue to do so. During an operation of these systems undesired effects, such as e.g. parasitic inductances, may occur. Manufacturers of semiconductor packages and electronic systems including semiconductor packages are constantly striving to improve their products. It may be desirable to develop semiconductor packages and electronic systems with better form factors and improved mounting schemes. At the same time it may be desirable to improve electronic performances of these devices.

### SUMMARY

An aspect of the present disclosure relates to a semiconductor package. The semiconductor package comprises a package body. The semiconductor package further comprises a semiconductor component encapsulated in the package body. The semiconductor package further comprises a cavity formed in a bottom surface of the package body.

According to one aspect of the disclosure, an arrangement of a conductor and an aluminum layer that are soldered together is described. The arrangement comprises a substrate. An aluminum layer is placed over the substrate, the aluminum.

DE 10 2017 012 210 A1 relates to the soldering of a conductor to an aluminum layer and shows an arrangement which contains a substitute metal layer over an aluminum metallization and a solder layer over which the conductor is connected.

A further aspect of the present disclosure relates to an electronic system. The electronic system comprises a circuit board. The electronic system further comprises a semiconductor package mounted on the circuit board. The semiconductor package comprises a package body. The semiconductor package further comprises a semiconductor component encapsulated in the package body. The semiconductor package further comprises a cavity formed in a bottom surface of the package body, wherein the bottom surface faces the circuit board. The electronic system further comprises an electronic component mounted on the circuit board, wherein the electronic component is arranged in the cavity.

### BRIEF DESCRIPTION OF THE DRAWINGS

The accompanying drawings are included to provide a further understanding of aspects. The drawings illustrate aspects and together with the description serve to explain principles of aspects. Other aspects and many of the intended advantages of aspects will be readily appreciated as they become better understood by reference to the following detailed description. The elements of the drawings are not necessarily to scale relative to each other. Like reference signs may designate corresponding similar parts.

FIG. 1 schematically illustrates a cross-sectional side view of a semiconductor package 100 in accordance with the disclosure.

FIG. 2 schematically illustrates a cross-sectional side view of an electronic system 200 in accordance with the disclosure.

FIG. 3 schematically illustrates a cross-sectional side view of a semiconductor package 300 in accordance with the disclosure.

FIG. 4 schematically illustrates a cross-sectional side view of an electronic system 400 in accordance with the disclosure.

FIG. 5 schematically illustrates a cross-sectional side view of a semiconductor package 500 in accordance with the disclosure.

FIG. 6 schematically illustrates a cross-sectional side view of an electronic system 600 in accordance with the disclosure.

FIG. 7 schematically illustrates a cross-sectional side view of an electronic system 700 in accordance with the disclosure.

FIG. 8 schematically illustrates a bottom view of a semiconductor package 800 in accordance with the disclosure.

FIG. 9 schematically illustrates a bottom view of a semiconductor package 900 in accordance with the disclosure.

FIG. 10 schematically illustrates a bottom view of a semiconductor package 1000 in accordance with the disclosure.

FIG. 11 schematically illustrates a cross-sectional side view of a semiconductor package 1100 in accordance with the disclosure.

FIG. 12 schematically illustrates a cross-sectional side view of a semiconductor package 1200 in accordance with the disclosure.

FIG. 13 schematically illustrates a cross-sectional side view of an electronic system 1300 in accordance with the disclosure.

FIG. 14 schematically illustrates a cross-sectional side view of an electronic system 1400 in accordance with the disclosure.

### DETAILED DESCRIPTION

In the following detailed description, reference is made to the accompanying drawings, in which are shown by way of illustration specific aspects in which the disclosure may be practiced. In this regard, directional terminology, such as “top”, “bottom”, “front”, “back”, etc. may be used with reference to the orientation of the figures being described. Since components of described devices may be positioned in a number of different orientations, the directional terminology may be used for purposes of illustration and is in no way limiting. Other aspects may be utilized and structural or logical changes may be made without departing from the concept of the present disclosure. Hence, the following detailed description is not to be taken in a limiting sense, and the concept of the present disclosure is defined by the appended claims.

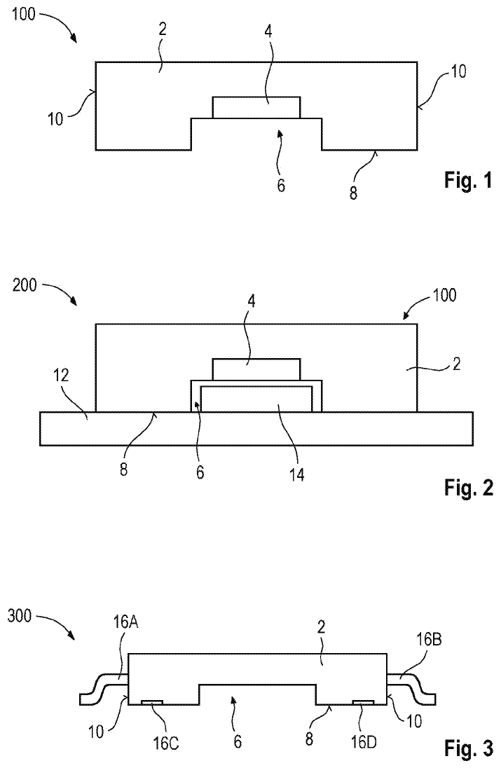

FIG. 1 schematically illustrates a cross-sectional side view of a semiconductor package 100 in accordance with the disclosure. The semiconductor package 100 is illustrated in a general manner in order to qualitatively specify aspects of the disclosure. The semiconductor package 100 may include further aspects which are not illustrated for the sake of simplicity. For example, the semiconductor package 100 may be extended by any of the aspects described in connection with other semiconductor packages or electronic systems in accordance with the disclosure. Comments made in connection with FIG. 1 may likewise hold true for other semiconductor packages or electronic systems described herein.

The semiconductor package 100 may include a package body 2. The semiconductor package 100 may further include a semiconductor component 4 encapsulated in the package body 2. A cavity 6 may be formed in a bottom surface 8 of the package body 2.

In general, the semiconductor package 100 may represent any plastic, ceramic, glass, etc. casing containing one or more semiconductor components, integrated circuits, electronic components (passive and/or active), etc. These components may be encapsulated or embedded in the package body 2. The package body 2 may be configured to protect the encapsulated components against threats, such as mechanical impact, chemical contamination, light exposure, etc.

In particular, an encapsulation material forming the package body 2 may be electrically insulating. For example, the encapsulation material may include at least one of an epoxy, a filled epoxy, a glass fiber filled epoxy, a glass fiber filled polymer, an imide, a filled or non-filled thermoplastic polymer material, a filled or non-filled duroplastic polymer material, a filled or non-filled polymer blend, a thermosetting material, a thermoplast material, a mold compound, a glob-top material, a laminate material, etc. Various techniques may be used to encapsulate components of the semiconductor package 100 with the encapsulation material, for example at least one of compression molding, injection molding, powder molding, liquid molding, lamination, etc.

For example, the semiconductor package 100 may be one of a leadless package, leaded package, surface mounted device (SMD), through hole device (THD), etc. More particular, the semiconductor package 100 may be of one of the following package types: DDPAK (Double DPAK (Decawatt Package)), QDPAK (Quadruple DPAK), SON (Small Outline No Lead), DFN (Dual Flat No Lead), QFN (Quad Flat No Lead), etc.

In the example of FIG. 1, only one semiconductor component 4 is illustrated for the sake of simplicity. In further examples, the semiconductor package 100 may include an arbitrary number of further electronic components or semiconductor components. The semiconductor component 4 may be formed as one or more semiconductor chips. The semiconductor chip(s) may include integrated electrical circuits, passives, etc. The integrated circuits may be designed as logic integrated circuits, analog integrated circuits, mixed signal integrated circuits, power integrated circuits, integrated passives, etc. In one example, the semiconductor chip(s) may be made of or may include an elemental semiconductor material, for example Si, etc. In a further example, the semiconductor chip(s) may be made of or may include a compound semiconductor material, for example GaN, SiC, SiGe, GaAs, etc.

The semiconductor component 4 may include one or more power semiconductors. Such power semiconductor chips may be configured as diodes, power MOSFETs (Metal Oxide Semiconductor Field Effect Transistors), IGBTs (Insulated Gate Bipolar Transistors), JFETs (Junction Gate Field Effect Transistors), HEMTs (High Electron Mobility Transistors), super junction devices, power bipolar transistors, etc. In one specific example, a power MOSFET may be a part of a half bridge circuit, of any other bridge circuit or of a cascode circuit. In this regard, the power MOSFET may e.g. form a low side switch or a high side switch.

The semiconductor package 100 may be configured to be mounted on a circuit board (not illustrated) with the bottom surface 8 of the package body 2 facing the circuit board. The bottom surface 8 may thus also be referred to as a mounting surface of the semiconductor package 100. The semiconductor package 100 may be electrically and mechanically connected to the circuit board via electrical contacts (not illustrated) of the semiconductor package 100. In one example (see e.g. FIG. 3), the electrical contacts of the semiconductor package 100 may protrude out of at least one of the side surfaces 10 of the package body 2. In such case, the semiconductor package 100 may be a leaded package (e.g. DDPAK, QDPAK), wherein the electrical contacts may e.g. be formed by leads of a leadframe. The electrical contacts may be of linear shape or may be bent (e.g. in a gull wing fashion). In particular, the electrical contacts may be bent in a direction towards a circuit board on which the semiconductor package 100 is to be mounted. In a further example (see e.g. FIG. 5), the electrical contacts of the semiconductor package 100 may be arranged on the bottom surface 8 of the package body 2. In such case, the semiconductor package 100 may be a leadless package (e.g. SON, DFN, QFN).

The cavity 6 may also be referred to as recess or hole. One or more electronic components may be arranged in the cavity 6 when the semiconductor package 100 is mounted on a circuit board. The dimensions of the cavity 6 may thus particularly depend on the dimensions of these electronic component(s). In one example, an electronic component that is to be arranged in the cavity 6 may be a semiconductor package, such as e.g. a QFN package. The semiconductor package may have a height in a range from about 150 μm to about 2.5 mm, more particular from about 200 μm to about 2.0 mm. Exemplary values of a footprint area of such semiconductor package may be about (5 mm)×(5 mm) or about (5 mm)×(6 mm). In a further example, an electronic component that is to be arranged in the cavity 6 may be a passive component, such as e.g. a capacitor. A height of a capacitor may have an exemplary value of about 500 μm. A height of a silicon capacitor (e.g. SilCap) may have an exemplary value of about 100 μm. An exemplary value of a footprint area of a passive component may be about (500 μm)×(1 mm). Taking into account the above specified dimensions of an electronic component arranged in the cavity 6, the cavity 6 may have a depth in a range from about 100 μm to about 4 mm. In addition, a bottom surface of the cavity 6 may have a surface area in a range from about 0.5 mm² to about 50 mm². For the case of multiple electronic components arranged in the cavity 6, the above specified dimensions of the cavity 6 may be scaled or multiplied accordingly.

FIG. 2 schematically illustrates a cross-sectional side view of an electronic system 200 in accordance with the disclosure. The electronic system 200 is illustrated in a general manner in order to qualitatively specify aspects of the disclosure. The electronic system 200 may include further aspects which are not illustrated for the sake of simplicity. For example, the electronic system 200 may be extended by any of the aspects described in connection with other electronic systems or semiconductor packages in accordance with the disclosure. Comments made in connection with FIG. 2 may likewise hold true for other electronic systems or semiconductor packages described herein.

The electronic system 200 may include a circuit board 12. The circuit board 12 may also be referred to as board, application board or printed circuit board (PCB). The electronic system 200 may further include a semiconductor package 100 mounted on the circuit board 12. For example, the semiconductor package 100 of FIG. 2 may be similar to the semiconductor package 100 of FIG. 1 such that comments made in connection with FIG. 1 may also hold true for FIG. 2. The electronic system 200 may further include an electronic component 14 which may be mounted on the circuit board 12 and may be arranged in the cavity 6. The electronic component 14 may include or may be a semiconductor package or a passive component as previously described in connection with FIG. 1.

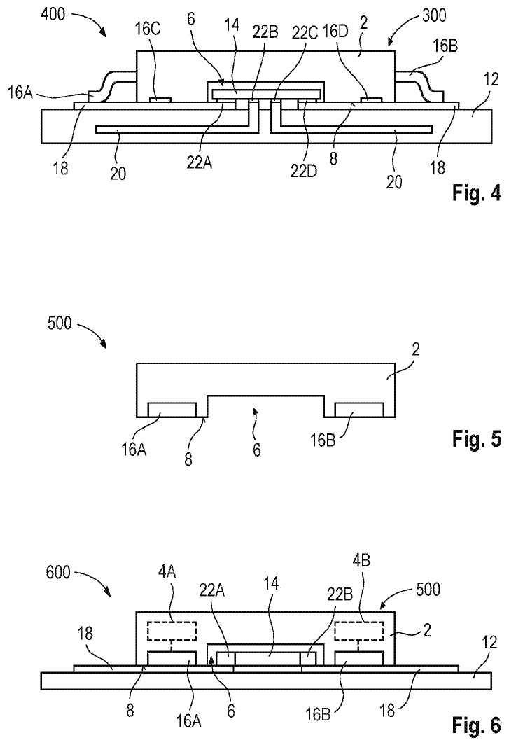

An electrical connection between the semiconductor component 4 and the electronic component 14 may be provided via conductive tracks and electrical contacts of the circuit board 12. In particular, the electrical connection may be exclusively provided via the circuit board 12. That is, the semiconductor package 100 and the electronic component 14 may only electrically interact with each other after a suitable electrical and mechanical connection to the circuit board 12. Exemplary electrical interconnections between a semiconductor package and an electronic component arranged in a cavity of the semiconductor package via a circuit board are shown in FIGS. 4 and 6.

According to an aspect the semiconductor package 100 may include a power semiconductor, and the electronic component 14 may include at least one of a driver circuit or a controller circuit configured to drive or control the power semiconductor. For example, the electronic system 200 may represent a PWM (Pulse Width Modulation) application, wherein the power part of the PWM application may be included in the semiconductor package 100 while the electronic component 14 may be configured to drive and/or control this power part. In further examples, the electronic system 200 may represent a power conversion application or a drive application.

A driver circuit may be configured to drive one or more electronic components, such as e.g. a high-power transistor. The driven components may be voltage driven or current driven. For example, Power MOSFETs, IGBTs, etc., may be voltage driven switches, because their insulated gate may particularly behave like a capacitor. Conversely, switches, such as triacs (triode for alternating current), thyristors, bipolar transistors, a PN diode, etc., may be current driven. In one example, driving a component including a gate electrode may be performed by a gate driver circuit. The driving process may include applying different voltages to the gate electrode, for example in form of turn-on and turn-off switching wave forms. In a further example, a driver circuit may be used to drive a direct driven circuit. A control circuit may be configured to control one or more drivers that drive components of the device. In one example, a control circuit may simultaneously control drivers of multiple direct driven circuits. For example, a half bridge circuit including two direct driven circuits may thus be controlled by a controller. A controller may e.g. include a micro controller. Referring back to the example of FIG. 2, the controller may be included in the electronic component 14 while the driver circuit(s) controlled by the control circuit may be either also included in the electronic component 14 or may be contained in the semiconductor package 100.

According to a further aspect the semiconductor package 100 may include a half bridge circuit with a high side switch and a low side switch, and the electronic component 14 may include a capacitor connected between the high side switch and the low side switch. For example, each of the high side switch and the low side switch may be formed by a power MOSFET. A half bridge circuit may e.g. be implemented in electronic circuits for converting DC voltages, i.e. DC-DC converters.

In conventional electronic systems electronic components and semiconductor packages may be mounted on a circuit board side by side. Compared to this, due to the arrangement of the electronic component 14 in the cavity 6 of the semiconductor package 100, the electronic system 200 may require less mounting area. Further, in conventional electronic systems electronic components and semiconductor packages may be stacked over each other when mounted over a circuit board. Compared to this, due to the arrangement of the electronic component 14 in the cavity 6 of the semiconductor package 100, the electronic system 200 may have a reduced height. Semiconductor packages and electronic systems in accordance with the disclosure may thus result in better form factors and may provide improved mounting schemes.

In conventional electronic systems electronic components and semiconductor packages may be stacked or arranged side by side on a circuit board. Compared to this, due to the arrangement of the electronic component 14 in the cavity 6 of the semiconductor package 100, one or more distances between the semiconductor component 4 of the semiconductor package 100 and the electronic component 14 may be reduced, i.e. these components may be arranged closer together. By reducing the distances between these components, parasitic inductances may be avoided or may be at least reduced.

FIG. 3 schematically illustrates a cross-sectional side view of a semiconductor package 300 in accordance with the disclosure. The semiconductor package 300 can be seen as a more detailed implementation of the semiconductor package 100 of FIG. 1. The semiconductor package 300 may include electrical contacts 16A, 16B protruding out of at least one of the side surfaces 10 of the package body 2. In the example of FIG. 3, the electrical contacts 16A, 16B may protrude out of two opposite side surfaces 10 of the package body 2. In a further example, the electrical contacts 16A, 16B may protrude out of only one side surface 10. In yet a further example, the electrical contacts 16A, 16B may protrude out of three or all four side surfaces 10 of the package body 2. In the example of FIG. 3, the semiconductor package 300 may be a leaded package (e.g. DDPAK, QDPAK) including electrical contacts 16A, 16B which may e.g. be formed by gull wing shaped leads of a leadframe. The semiconductor package 300 may further include optional electrical contacts 16C, 16D arranged on the bottom surface 8 of the package body 2. The electrical contacts 16A to 16D of the semiconductor package 300 may be configured to provide an electrical connection to electronic components or semiconductor components encapsulated in the package body 2 such that these components may be electronically accessible from outside of the package body 2.

FIG. 4 schematically illustrates a cross-sectional side view of an electronic system 400 in accordance with the disclosure. The electronic system 400 may include a circuit board 12 with conductive tracks 18 arranged on the upper and/or lower surface of the circuit board 12. In addition, the circuit board 12 may include an electrical redistribution structure 20 which may at least partly be arranged inside of the circuit board 12 and which may be configured to provide a redistribution of electrical signals between electrical contacts arranged on the upper and/or lower surface of the circuit board 12. The conductive tracks 18 and the electrical redistribution structure 20 of FIG. 4 are illustrated in a qualitative manner. A semiconductor package 300 may be mounted on the circuit board 12. The semiconductor package 300 of FIG. 4 may be similar to the semiconductor package 300 of FIG. 3 such that comments made in connection with FIG. 3 may also hold true for FIG. 4.

The electronic system 400 may include an electronic component 14 arranged in the cavity 6 between the bottom surface 8 of the package body 2 and the upper surface of the circuit board 12. For example, the electronic component 14 may be a semiconductor package, such as e.g. a QFN package. In the example of FIG. 4, the electronic component 14 may be mounted on the circuit board 12, wherein electrical contacts 22A to 22D of the electronic component 14 may be electrically and mechanically connected to the circuit board 12. In the example of FIG. 4, the electrical contacts 22A, 22D of the electronic component 14 may be electrically connected to one or more of electrical contacts 16A to 16D of the semiconductor package 300 via the conductive tracks 18 of the circuit board 12. In addition, the electrical contacts 22B, 22C of the electronic component 14 may be electrically connected to further components (not illustrated) of the electronic system 400 via the electrical redistribution structure 20 of the circuit board 12. In the example of FIG. 4, an electrical connection between the semiconductor package 300 and the electronic component 14 may be exclusively provided via the circuit board 12 in particular.

FIG. 5 schematically illustrates a cross-sectional side view of a semiconductor package 500 in accordance with the disclosure. The semiconductor package 500 can be seen as a more detailed implementation of the semiconductor package 100 of FIG. 1. The semiconductor package 500 may include electrical contacts 16A, 16B arranged on the bottom surface 8 of the package body 2. In the example of FIG. 5, the semiconductor package 500 may be a leadless package (e.g. SON, DFN, QFN). When viewed in a direction perpendicular to the bottom surface 8, the electrical contacts 16A, 16B may be arranged in an outline of the package body 2. The electrical contacts 16A, 16B of the semiconductor package 500 may be configured to provide an electrical connection to electronic or semiconductor components encapsulated in the package body 2 such that these components may be electronically accessible from outside of the package body 2.

FIG. 6 schematically illustrates a cross-sectional side view of an electronic system 600 in accordance with the disclosure. The electronic system 600 may include similar components as described in connection with the electronic system 400 of FIG. 4. A semiconductor package 500 may be mounted on the circuit board 12. The semiconductor package 500 of FIG. 6 may be similar to the semiconductor package 500 of FIG. 5 such that comments made in connection with FIG. 5 may also hold true for FIG. 6. An electronic component 14 may be arranged in the cavity 6 between the bottom surface 8 of the package body 2 and the upper surface of the circuit board 12. For example, the electronic component 14 may be a passive component, such as e.g. a capacitor. Electrical contacts 22A, 22B of the electronic component 14 may be electrically connected to the electrical contacts 16A, 16B of the semiconductor package 500 via conductive tracks 18 of the circuit board 12. For example, an electrical connection between the semiconductor package 500 and the electronic component 14 may be exclusively provided via the circuit board 12 in particular.

In one example, the semiconductor package 500 (or the semiconductor package 300) may include two semiconductor components 4A, 4B in form of two power MOSFETs. In FIG. 6, the semiconductor components 4A, 4B and their electrical connections to the electrical contacts 16A, 16B are qualitatively illustrated by dashed lines. The two power MOSFETs may e.g. form a low side switch and a high side switch of a (power) half bridge circuit. Here, the electrical contacts 16A, 16B may be electrically connected to the low side switch and high side switch, respectively. The electronic component 14 may include a capacitor which may be connected between the high side switch and the low side switch of the half bridge circuit. Due to such circuit layout, the cavity 6 (and thus the capacitor arranged therein) may particularly be arranged between the electrical contacts 16A, 16B when viewed in a direction substantially perpendicular to the bottom surface 8 of the package body 2. In a similar fashion, the cavity 6 (and thus the capacitor arranged therein) may be arranged between the first semiconductor component 4A and the second semiconductor component 4B, i.e. between the two power MOSFETs.

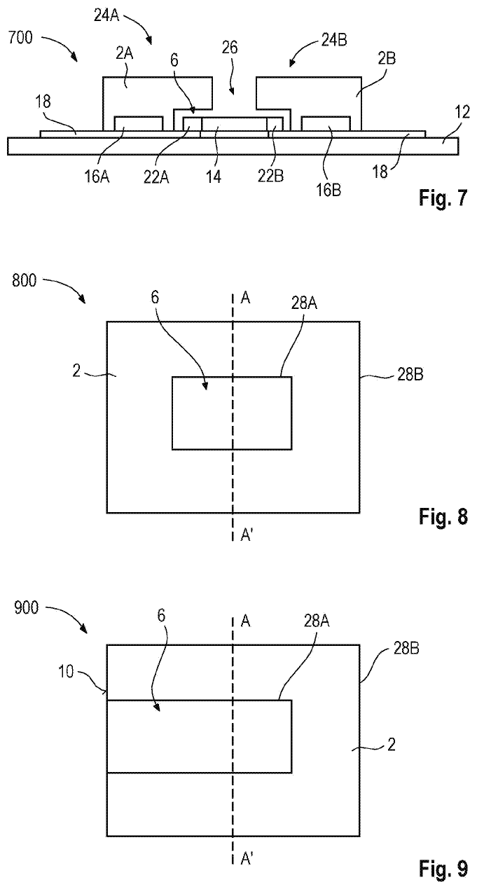

FIG. 7 schematically illustrates a cross-sectional side view of an electronic system 700 in accordance with the disclosure. The electronic system 700 may be at least partly similar to the electronic system 600 of FIG. 6. In contrast to FIG. 6, the electronic system 700 may include two semiconductor packages 24A, 24B mounted on the circuit board 12 instead of only one semiconductor package. The first semiconductor package 24A having a first package body 2A may be mounted on the circuit board 12 via a first electrical contact 16A. The second semiconductor package 24B having a second package body 2B may be mounted on the circuit board 12 via a second electrical contact 16B. For example, the first semiconductor package 24A may include a first power MOSFET configured to form a low side switch of a half bridge circuit, and the second semiconductor package 24B may include a second power MOSFET configured to form a high side switch of the half bridge circuit.

The semiconductor packages 24A, 24B may be arranged on the circuit board 12 such that an opening 26 may be formed between the first semiconductor package 24A and the second semiconductor package 24B. In particular, the opening 26 may be arranged over the electronic component 14. The cavity 6 and the electronic component 14 arranged therein may thus be accessible through the opening 24. For example, an encapsulation material or coating material (not illustrated) may be disposed into the cavity 6 through the opening 24 and may at least partly cover the electronic component 14. Compared to FIG. 6, the cavity 6 in FIG. 7 may be formed by recesses formed in two semiconductor packages instead of only one semiconductor package.

FIGS. 8 to 10 schematically illustrate bottom views of semiconductor packages 800 to 1000 in accordance with the disclosure. In general, an outline or footprint of a cavity formed in a package body of a semiconductor package in accordance with the disclosure may be of arbitrary shape when viewed in a direction substantially perpendicular to the bottom surface of the package body. Exemplary shapes of cavities are illustrated in the bottom views of FIGS. 8 to 10. For example, cross-sectional side views of semiconductor packages described in connection with foregoing figures may extend along a dashed line A-A′.

FIG. 8 illustrates an example in which an outline 28A of the cavity 6 may be completely arranged in an outline 28B of the package body 2. The cavity 6 and an electronic component arranged therein may thus be covered by all four side surfaces of the package body 2.

FIG. 9 illustrates an example in which the cavity 6 may extend into the package body 2 from a first side surface 10 of the package body 2. The cavity 6 may form a tunnel extending into the package body 2. The cavity 6 and an electronic component arranged therein may be covered by three side surfaces of the package body 2 while one side surface of the package body 2 may have an opening. For example, the opening may be used for optical inspection purposes. Further, an encapsulation material or coating material may be disposed into the cavity 6 through the opening and may at least partly cover the electronic component 14.

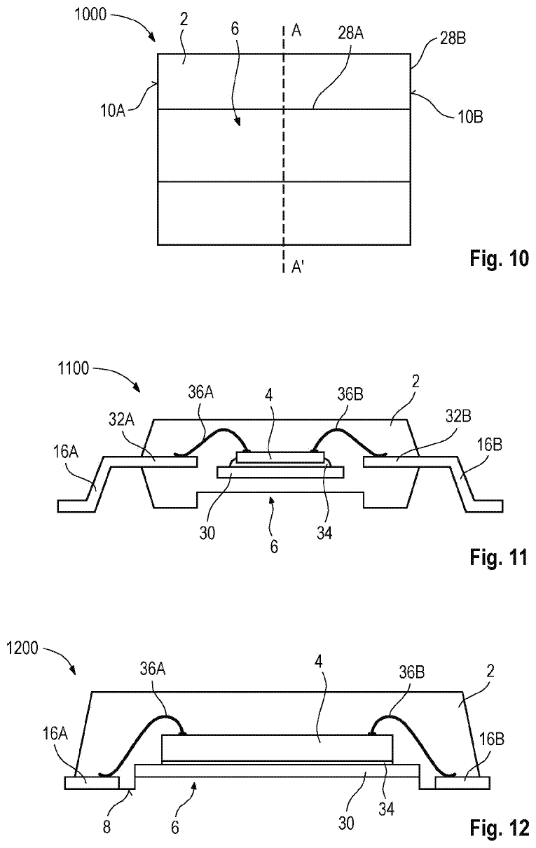

In the example of FIG. 10, the cavity 6 may extend through the package body 2 from a first side surface 10A of the package body 2 to a second side surface 10B of the package body 2. The cavity 6 may form a tunnel fully extending through the package body 2. The electronic component 14 may be enclosed or covered by two opposite side surfaces of the package body 2 while two further opposite side surfaces of the package body 2 may have openings. Similar to FIG. 9, the openings may be used for an optical inspection or a deposition of a coating material.

In the examples of FIGS. 8 to 10, the outline 28A of the cavity 6 may be of rectangular shape. In further examples, the outline 28A of the cavity 6 may be of a different shape, for example circular, elliptical, polygonal, etc.

FIGS. 11 and 12 schematically illustrate cross-sectional side views of semiconductor packages 1100 and 1200 in accordance with the disclosure. The figures show an exemplary and non-limiting package type and inner structure of semiconductor packages in accordance with the disclosure for illustrative purposes. Other semiconductor packages in accordance with the disclosure may be of a different package type. For example, a package body of such other semiconductor packages may include or may be made of a laminate.

The semiconductor package 1100 of FIG. 11 may e.g. be similar to the semiconductor package 300 of FIG. 3. The semiconductor package 1100 may include a chip carrier in form of a leadframe. The leadframe may include one or more diepads 30 as well as one or more leads 32A, 32B. The leadframe may be fabricated from metals and/or metal alloys, in particular at least one of copper, copper alloys, nickel, iron nickel, aluminum, aluminum alloys, steel, stainless steel, etc. The semiconductor component 4 may be attached to the diepad 30 by means of a die attach material 34. Electrical contacts 16A, 16B of the semiconductor package 1100 may be formed by the leads 32A, 32B. Electrical contacts of the semiconductor component 4 may be electrically connected to the electrical contacts 16A, 16B of the semiconductor package 1100 via electrical connection elements 32A, 32B, such as e.g. bond wires, clips, ribbons.

The semiconductor package 1200 of FIG. 12 may e.g. be similar to the semiconductor package 500 of FIG. 5. In addition, the semiconductor package 1200 may include similar components as described in connection with FIG. 11. In contrast to FIG. 11, the leads of the leadframe may form electrical contacts 16A, 16B arranged on the bottom surface 8 of the package body 2 and the diepad 30 may have an uncovered surface which may form a ceiling of the cavity 6.

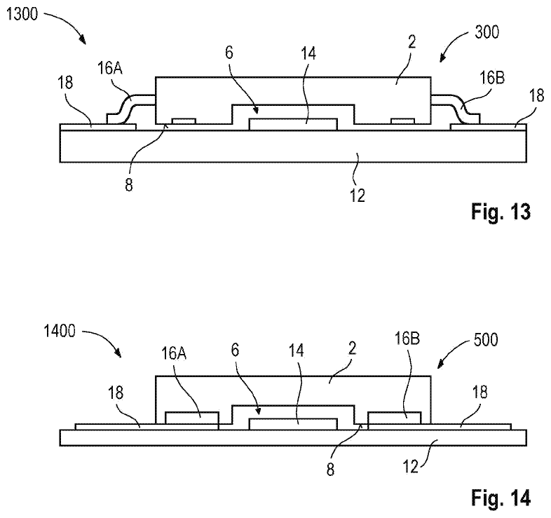

FIG. 13 schematically illustrates a cross-sectional side view of an electronic system 1300 in accordance with the disclosure. The electronic system 1300 may e.g. include similar components as described in connection with the electronic system 400 of FIG. 4. A semiconductor package 300 may be mounted on the circuit board 12. The semiconductor package 300 of FIG. 13 may be similar to the semiconductor package 300 of FIG. 3. An electronic component 14 may be arranged in the cavity 6 between the bottom surface 8 of the package body 2 and the upper surface of the circuit board 12. In the example of FIG. 13, the electronic component 14 may include or may be one or multiple conductive tracks. The conductive track may be part of a wiring of the circuit board 12 which may be inter alia arranged on the surface of the circuit board 12 facing the semiconductor package 300. In particular, the conductive track may be configured to carry high currents and/or may be configured to operate at high voltages. For example, a maximum value of such high voltages may be greater than about 600V or greater than about 1200V or even greater than about 1700V. In one specific example, the circuit board 12 may be an insulated metal substrate (IMS) which may particularly include only one wiring layer.

The conductive track may at least partly cross the semiconductor package 300 when viewed in a direction substantially perpendicular to the bottom surface 8 of the package body 2. For example, referring back to FIG. 10, the conductive track may cross the semiconductor package 300 from one side surface of the package body 2 to an opposite side surface of the package body 2 by passing through the tunnel formed by the cavity 6. An additional routing of the conductive track around the semiconductor package 300 may thus be avoided. In the example of FIG. 13, the conductive track is illustrated to be electrically insulated from the semiconductor package 300 and its components. In further examples, the conductive track may be electrically connected to the semiconductor package 300, i.e. to one or more of its components.

FIG. 14 schematically illustrates a cross-sectional side view of an electronic system 1400 in accordance with the disclosure. The electronic system 1400 may be similar to the electronic system 1300 of FIG. 1300. Compared to the semiconductor package 300 of FIG. 13, the semiconductor package 500 of FIG. 14 may be of a different type. For example, the semiconductor package 500 of FIG. 14 may be similar to the semiconductor package 500 of FIG. 5. Similar to FIG. 13, the electronic component 14 may include or may be one or multiple conductive track(s) such that corresponding comments in connection with FIG. 13 may also hold true for FIG. 14.

Semiconductor packages and electronic devices described in connection with foregoing examples are illustrated to include only one cavity. It is noted that further semiconductor packages and electronic components in accordance with the disclosure may include an arbitrary number of more than one cavity. In addition, each of the cavities may include an arbitrary number of electronic components arranged therein. A variety of further embodiments may be in accordance with the disclosure, but is not explicitly illustrated and described for the sake of simplicity.

### EXAMPLES

In the following, semiconductor packages and electronic systems will be explained by means of examples.

Example 1 is a semiconductor package, comprising: a package body; a semiconductor component encapsulated in the package body; and a cavity formed in a bottom surface of the package body.

Example 2 is a semiconductor package according to Example 1, wherein the semiconductor package is configured to be mounted on a circuit board with the bottom surface of the package body facing the circuit board.

Example 3 is a semiconductor package according to Example 1 or 2, further comprising: electrical contacts protruding out of at least one side surface of the package body.

Example 4 is a semiconductor package according to one of the preceding Examples, further comprising: electrical contacts arranged on the bottom surface of the package body.

Example 5 is a semiconductor package according to Example 3 or 4, wherein, when viewed in a direction perpendicular to the bottom surface of the package body, the cavity is arranged between at least two of the electrical contacts.

Example 6 is a semiconductor package according to one of the preceding Examples, further comprising: a further semiconductor component encapsulated in the package body, wherein, when viewed in a direction perpendicular to the bottom surface of the package body, the cavity is arranged between the semiconductor component and the further semiconductor component.

Example 7 is a semiconductor package according to one of the preceding Examples, wherein the cavity extends into the package body from a first side surface of the package body.

Example 8 is a semiconductor package according to one of the preceding Examples, wherein the cavity extends through the package body from a first side surface of the package body to a second side surface of the package body.

Example 9 is a semiconductor package according to one of Examples 1 to 6, wherein, when viewed in a direction perpendicular to the bottom surface of the package body, an outline of the cavity is completely arranged in an outline of the package body.

Example 10 is a semiconductor package according to one of the preceding Examples, wherein the cavity has a depth in a range from 100 μm to 4 mm.

Example 11 is a semiconductor package according to one of the preceding Examples, wherein a bottom surface of the cavity has a surface area in a range from 0.5 mm² to 50 mm².

Example 12 is a semiconductor package according to one of the preceding Examples, wherein the semiconductor component comprises a power semiconductor.

Example 13 is a semiconductor package according to one of the preceding Examples, further comprising: a leadframe, wherein the leadframe is encapsulated in the package body and the semiconductor component is mounted on the leadframe.

Example 14 is an electronic system, comprising: a circuit board; a semiconductor package mounted on the circuit board, the semiconductor package comprising: a package body, a semiconductor component encapsulated in the package body, and a cavity formed in a bottom surface of the package body, wherein the bottom surface faces the circuit board; and an electronic component mounted on the circuit board, wherein the electronic component is arranged in the cavity.

Example 15 is an electronic system according to Example 14, wherein the electronic component comprises a semiconductor package.

Example 16 is an electronic system according to Example 14 or 15, wherein the electronic component comprises a passive component.

Example 17 is an electronic system according to one of Examples 14 to 16, wherein the electronic component comprises a conductive track.

Example 18 is an electronic system according to one of Examples 14 to 17, wherein an electrical connection between the semiconductor component and the electronic component is exclusively provided via the circuit board.

Example 19 is an electronic system according to one of Examples 14 to 18, wherein: the semiconductor package comprises a power semiconductor, and the electronic component comprises at least one of a driver circuit or a controller circuit configured to drive or control the power semiconductor.

Example 20 is an electronic system according to one of Examples 14 to 19, wherein: the semiconductor package comprises a half bridge circuit comprising a high side switch and a low side switch, and the electronic component comprises a capacitor connected between the high side switch and the low side switch.

Example 21 is an electronic system according to one of Examples 14 to 20, further comprising: a further semiconductor package mounted on the circuit board, the further semiconductor package comprising: a package body, a semiconductor component encapsulated in the package body, and a cavity formed in a bottom surface of the package body, wherein the bottom surface faces the circuit board, wherein the electronic component is arranged in the cavity of the further semiconductor package.

Example 22 is an electronic system according to Example 21, further comprising: an opening formed between the semiconductor package and the further semiconductor package, wherein the opening is arranged over the electronic component.

As employed in this description, the terms “connected”, “coupled”, “electrically connected” and/or “electrically coupled” may not necessarily mean that elements must be directly connected or coupled together. Intervening elements may be provided between the “connected”, “coupled”, “electrically connected” or “electrically coupled” elements.

Further, the words “over” or “on” used with regard to e.g. a material layer formed or located “over” or “on” a surface of an object may be used herein to mean that the material layer may be located (e.g. formed, deposited, etc.) “directly on”, e.g. in direct contact with, the implied surface. The words “over” or “on” used with regard to e.g. a material layer formed or located “over” or “on” a surface may also be used herein to mean that the material layer may be located (e.g. formed, deposited, etc.) “indirectly on” the implied surface with e.g. one or more additional layers being arranged between the implied surface and the material layer.

Furthermore, to the extent that the terms “having”, “containing”, “including”, “with” or variants thereof are used in either the detailed description or the claims, such terms are intended to be inclusive in a manner similar to the term “comprising”. That is, as used herein, the terms “having”, “containing”, “including”, “with”, “comprising” and the like are open-ended terms that indicate the presence of stated elements or features, but do not preclude additional elements or features.

Moreover, the word “exemplary” is used herein to mean serving as an example, instance, or illustration. Any aspect or design described herein as “exemplary” is not necessarily to be construed as advantageous over other aspects or designs. Rather, use of the word “exemplary” is intended to present concepts in a concrete fashion.

Devices are described herein. Comments made in connection with a described device may also hold true for a corresponding method for manufacturing such device. For example, if a specific component of a device is described, a corresponding method for manufacturing the device may include an act of providing the component in a suitable manner, even if such act is not explicitly described or illustrated in the figures.

While this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

1. A semiconductor package, comprising:
a package body;
a semiconductor component encapsulated in the package body; and
a cavity formed in a bottom surface of the package body, wherein the cavity extends into the package body from a first side surface of the package body.

2. The semiconductor package of claim 1, wherein the semiconductor package is configured to be mounted on a circuit board with the bottom surface of the package body facing the circuit board.

3. The semiconductor package of claim 1, further comprising:
electrical contacts protruding out of at least one side surface of the package body.

4. The semiconductor package of claim 1, further comprising:
electrical contacts arranged on the bottom surface of the package body.

5. The semiconductor package of claim 3, wherein, when viewed in a direction perpendicular to the bottom surface of the package body, the cavity is arranged between at least two of the electrical contacts.

6. The semiconductor package of claim 1, further comprising:
a further semiconductor component encapsulated in the package body, wherein, when viewed in a direction perpendicular to the bottom surface of the package body, the cavity is arranged between the semiconductor component and the further semiconductor component.

7. The semiconductor package of claim 1, wherein the cavity extends through the package body from a first side surface of the package body to a second side surface of the package body.

8. The semiconductor package of claim 1, wherein the cavity has a depth in a range from 100 μm to 4 mm.

9. The semiconductor package of claim 1, wherein a bottom surface of the cavity has a surface area in a range from 0.5 mm² to 50 mm².

10. The semiconductor package of claim 1, wherein the semiconductor component comprises a power semiconductor.

11. The semiconductor package of claim 1, further comprising:
a leadframe, wherein the leadframe is encapsulated in the package body and the semiconductor component is mounted on the leadframe.

12. An electronic system, comprising:
a circuit board;
a semiconductor package mounted on the circuit board, the semiconductor package comprising:
a package body,
a semiconductor component encapsulated in the package body, and
a cavity formed in a bottom surface of the package body, wherein the bottom surface faces the circuit board; and
an electronic component mounted on the circuit board, wherein the electronic component is at least partially arranged in the cavity.

13. The electronic system of claim 12, wherein the electronic component comprises a semiconductor package.

14. The electronic system of claim 12, wherein the electronic component comprises a passive component.

15. The electronic system of claim 12, wherein the electronic component comprises a conductive track.

16. The electronic system of claim 12, wherein an electrical connection between the semiconductor component and the electronic component is exclusively provided via the circuit board.

17. The electronic system of claim 12, wherein:
the semiconductor package comprises a power semiconductor, and
the electronic component comprises at least one of a driver circuit or a controller circuit configured to drive or control the power semiconductor.

18. The electronic system of claim 12, wherein:
the semiconductor package comprises a half bridge circuit comprising a high side switch and a low side switch, and
the electronic component comprises a capacitor connected between the high side switch and the low side switch.

19. The electronic system of claim 12, further comprising:
a further semiconductor package mounted on the circuit board, the further semiconductor package comprising:
a package body,
a semiconductor component encapsulated in the package body, and
a cavity formed in a bottom surface of the package body, wherein the bottom surface faces the circuit board, wherein the electronic component is arranged in the cavity of the further semiconductor package.

20. The electronic system of claim 19, further comprising:
an opening formed between the semiconductor package and the further semiconductor package, wherein the opening is arranged over the electronic component.
